(19) United States
(12) Patent Application Publication
(10) Pub. No.: US 2025/0331434 A1
(43) Pub. Date: Oct. 23, 2025

(54) SEMICONDUCTOR DEVICE AND MANUFACTURING METHOD OF SEMICONDUCTOR DEVICE

(71) Applicant: SK hynix Inc., Icheon-si (KR)

(72) Inventors: Seong Hyun Hwang, Icheon-si (KR); Nam Kyun Park, Icheon-si (KR); Tae Hyung Park, Icheon-si (KR); Jeong Hoon Bae, Icheon-si (KR); Dong Ho Shin, Icheon-si (KR); Jeong Ho Yeon, Icheon-si (KR); Dong Yeol Yun, Icheon-si (KR); Seo Rin Cho, Icheon-si (KR); Seong Hwang, Icheon-si (KR)

(21) Appl. No.: 18/789,232

(22) Filed: Jul. 30, 2024

(30) Foreign Application Priority Data
Apr. 23, 2024 (KR) 10-2024-0053902

(51) Int. Cl. H10N 70/00; H10B 61/00; H10B 63/00; H10N 50/01; H10N 50/10; H10N 50/80

(52) U.S. Cl. CPC H10N 70/841; H10B 61/10; H10B 63/24; H10N 50/01; H10N 50/10; H10N 50/80; H10N 70/011

(57) ABSTRACT

A semiconductor device may include: a first electrode including at least one first material layer and at least one second material layer that are alternately stacked, the first material layer and the second material layer having different work functions; a second electrode; and a variable resistance layer located between the first electrode and the second electrode.

### CROSS-REFERENCE TO RELATED APPLICATION

This application claims priority under 35 U.S.C. § 119 to Korean Patent Application No. 10-2024-0053902 filed Apr. 23, 2024, which is incorporated herein by reference in its entirety.

### BACKGROUND

### 1. Technical Field

Embodiments of the present disclosure relate to an electronic device, and more particularly, to a semiconductor device and a manufacturing method of the semiconductor device.

### 2. Related Art

Recently, in accordance with miniaturization, low power consumption, performance improvement, diversification, and the like, of electronic devices, semiconductor devices capable of storing information have been demanded in various electronic devices such as computers and portable communication devices. Accordingly, research into a semiconductor device capable of storing data using characteristics of switching between different resistance states depending on an applied voltage or current has been conducted. Examples of such a semiconductor device include a resistive random access memory (RRAM), a phase-change random access memory (PRAM), a ferroelectric random access memory (FRAM), a magnetic random access memory (MRAM), and the like.

### SUMMARY

In an embodiment, a semiconductor device may include: a first electrode including at least one first material layer and at least one second material layer that are alternately stacked, the first material layer and the second material layer having different work functions; a second electrode; and a variable resistance layer located between the first electrode and the second electrode.

In an embodiment, a semiconductor device may include: a first electrode including first conductive layers and first adhesive layers that are alternately stacked; a second electrode; a variable resistance layer located between the first electrode and the second electrode; and a liner layer extending along a sidewall of the first electrode and in contact with the first adhesive layers.

In an embodiment, a manufacturing method of a semiconductor device may include: forming a first electrode layer including at least one first material layer and at least one second material layer that are alternately stacked, the first material layer and the second material layer having different work functions; forming a variable resistance layer on the first electrode layer; and forming a second electrode layer on the variable resistance layer.

### BRIEF DESCRIPTION OF THE DRAWINGS

FIG. 1 is a diagram illustrating the structure of a semiconductor device in accordance with an embodiment.

FIG. 2 is a diagram illustrating the structure of a semiconductor device in accordance with an embodiment.

FIGS. 3A and 3B are diagrams for describing the structure of a semiconductor device in accordance with an embodiment.

FIGS. 4A and 4B are diagrams for describing the structure of a semiconductor device in accordance with an embodiment.

FIG. 5 is a diagram illustrating the structure of a semiconductor device in accordance with an embodiment.

FIGS. 6A, 6B, 7A, 7B, 7C, 7D, 7E, and 7F are diagrams for describing a manufacturing method of a semiconductor device in accordance with an embodiment.

### DETAILED DESCRIPTION

Various embodiments are directed to a semiconductor device having a stable structure and improved characteristics and a manufacturing method of the semiconductor device.

It is possible to improve the degree of integration, operating characteristics, and reliability of a semiconductor device.

Hereafter, some embodiments of the present disclosure will be described with reference to the accompanying drawings. As used herein, including in the claims, “or” as used in a list of items (e.g., a list of items prefaced by a phrase such as “at least one of” or “one or more of” or “one or both of”) indicates an inclusive list such that, for example, a list of at least one of A, B, or C indicates A or B or C or AB or AC or BC or ABC (i.e., A and B and C).

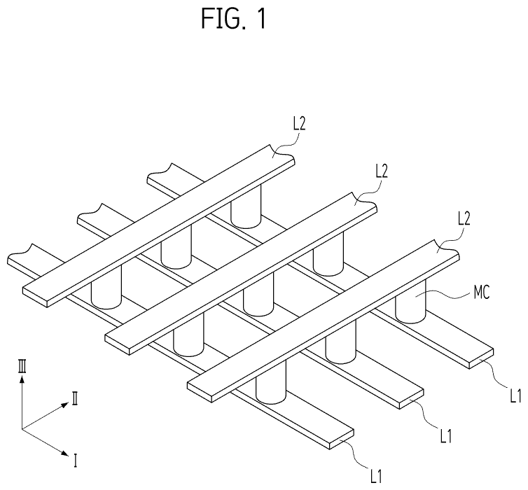

FIG. 1 is a diagram illustrating the structure of a semiconductor device in accordance with an embodiment.

Referring to FIG. 1, the semiconductor device in accordance with an embodiment may include at least one first access line L1, at least one second access line L2, and at least one memory cell MC.

The first access line L1 may extend in a first direction I. The second access line L2 may extend in a second direction II intersecting the first direction I. The first access line L1 and the second access line L2 may be stacked in a third direction III. The third direction III may be a direction perpendicular to a plane defined by the first direction I and the second direction II. The first access line L1 and the second access line L2 may be a word line or a bit line. As an example, the first access line L1 may be a word line, and the second access line L2 may be a bit line. Alternatively, the first access line L1 may be a bit line, and the second access line L2 may be a word line.

The memory cell MC may be located in a region where the first access line L1 and the second access line L2 intersect each other. The memory cells MC may be arranged in the first direction I and the second direction II. The memory cell MC may be connected between the first access line L1 and the second access line L2.

The memory cell MC may include a first electrode, a second electrode, and a variable resistance layer located between the first electrode and the second electrode. It is also possible for the memory cell MC to include a switching layer instead of the variable resistance layer or include both the variable resistance layer and the switching layer. The memory cell MC may further include a liner layer extending along a sidewall of the first electrode, a sidewall of the second electrode, and a sidewall of the variable resistance layer. At least one of the first electrode or the second electrode may include an adhesive layer.

In addition, although not illustrated in FIG. 1, the semiconductor device may further include circuits for controlling the first access lines L1 and the second access lines L2. As an example, the semiconductor device may include a first circuit such as a word line decoder and a word line driver. The first circuit may select a first access line on which a program operation is to be performed according to a row address. The semiconductor device may include a second circuit such as a bit line decoder and a bit line driver. The second circuit may select a second access line on which a program operation is to be performed according to a column address. During the program operation, a memory cell MC connected between the selected first access line L1 and the selected second access line L2 may be selected.

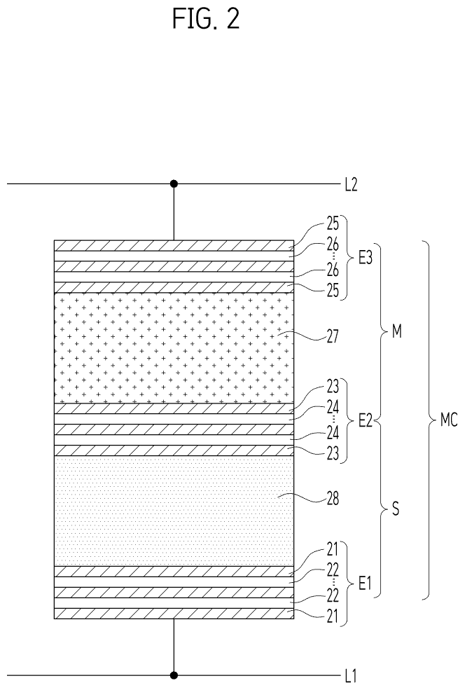

FIG. 2 is a diagram illustrating the structure of a semiconductor device in accordance with an embodiment. Hereinafter, the content overlapping with the previously described content may be omitted for the interest of brevity.

Referring to FIG. 2, a memory cell MC may include a selection element S and a memory element M. The selection element S may adjust a flow of current according to a magnitude of an applied voltage or current. The memory cell MC may be selected depending on turn-on or turn-off of the selection element S. The selection element S may include a first electrode E1, a switching layer 28, and a second electrode E2. The switching layer 28 may be located between the first electrode E1 and the second electrode E2. The switching layer 28 may maintain a specific phase such as an amorphous phase during an operation of the memory cell MC. As an example, the switching layer 28 may include a chalcogenide material. The first electrode E1 may be located between the switching layer 28 and a first access line L1, and may be electrically connected to the first access line L1.

The memory element M may include the second electrode E2, a variable resistance layer 27, and a third electrode E3. The variable resistance layer 27 may be located between the second electrode E2 and the third electrode E3. The selection element S and the memory element M may share the second electrode E2 with each other. The third electrode E3 of the memory element M may be electrically connected to a second access line L2.

The variable resistance layer 27 may have characteristics of reversibly transitioning between different resistance states depending on a voltage or a current applied to the memory element M. As an example, when the variable resistance layer 27 has a low resistance state, data ‘1’ may be stored, and when the variable resistance layer 27 has a high resistance state, data ‘0’ may be stored.

As an example, the variable resistance layer 27 may include a resistive material. An electrical path is generated or disappears in the variable resistance layer 27, such that data may be stored. As an example, the variable resistance layer 27 may include transition metal oxide or include metal oxide such as a perovskite-based material.

As an example, the variable resistance layer 27 may have a magnetic tunnel junction (MTJ) structure including a magnetization pinned layer, a tunnel barrier layer, and a magnetization free layer. The data may be stored according to a change in magnetization direction of the magnetization free layer with respect to a magnetization direction of the magnetization pinned layer. As an example, the magnetization pinned layer and the magnetization free layer may each include a magnetic material, and the tunnel barrier layer may include metal oxide.

As an example, the variable resistance layer 27 may include a phase change material or include a chalcogenide-based material. The variable resistance layer 27 may change its phase according to a program operation. As an example, the variable resistance layer 27 may have a low-resistance crystalline state through a set operation. As an example, the variable resistance layer 27 may have a high-resistance amorphous state through a reset operation. Accordingly, the data may be stored in the memory cell using a resistance difference depending on a phase of the variable resistance layer 27.

As an example, the variable resistance layer 27 may include a variable resistance material whose resistance changes without a phase change or include a chalcogenide-based material. The variable resistance layer 27 may maintain its phase after the program operation. As an example, the variable resistance layer 27 may have an amorphous state, and may maintain the amorphous state without changing to a crystalline state after the program operation. A threshold voltage of the memory cell may be changed depending on a program voltage applied to the memory cell, and the memory cell may be programmed to at least two states. As an example, the memory cell may be programmed to a set state or a reset state using program voltages having different polarities. Accordingly, the data may be stored in the memory cell using a difference in the threshold voltage of the memory cell.

At least one of the first electrode E1, the second electrode E2, or the third electrode E3 may include an adhesive layer. The adhesive layer may be used as an electrode and used to increase adhesive force between layers. As an example, at least one of the first electrode E1, the second electrode E2, or the third electrode E3 may have a laminate structure. The laminate structure may include conductive layers and adhesive layers that are alternately stacked, and the adhesive layers may be exposed through sidewalls.

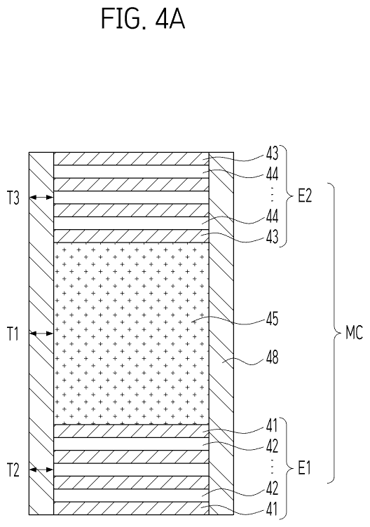

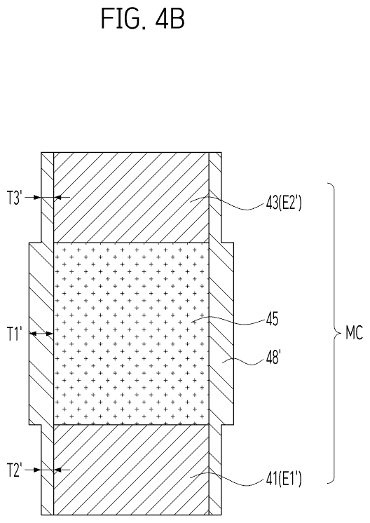

The first electrode E1 may include at least one first material layer 21 and at least one second material layer 22 that are alternately stacked. The second electrode E2 may include at least one third material layer 23 and at least one fourth material layer 24 that are alternately stacked. The third electrode E3 may include at least one fifth material layer 25 and at least one sixth material layer 26 that are alternately stacked. The first material layer 21, the third material layer 23, and the fifth material layer 25 may be conductive layers serving as electrodes. The second material layer 22, the fourth material layer 24, and the sixth material layer 26 may be adhesive layers for increasing adhesive force between layers. The second material layer 22, the fourth material layer 24, and the sixth material layer 26 may be conductive layers serving as both electrodes and adhesive layers. The second material layer 22 may have a different work function from the first material layer 21, the fourth material layer 24 may have a different work function from the third material layer 23, and the sixth material layer 26 may have a different work function from the fifth material layer 25. Through a difference in work function, a dipole layer may be formed at an interface between the layers, and the adhesive force may be increased by the dipole layer. This will be described in more detail with reference to FIGS. 4A and 4B.

The first to sixth material layers 21 to 26 may each include at least one of polysilicon, tungsten (W), tungsten nitride (WNₓ), tungsten silicide (WSiₓ), titanium (Ti), titanium nitride (TiNₓ), titanium silicon nitride (TiSiN), titanium aluminum nitride (TiAlN), tantalum (Ta), tantalum nitride (TaN), tantalum silicon nitride (TaSiN), tantalum aluminum nitride (TaAlN), carbon (C), silicon carbide (SiC), silicon carbonitride (SiCN), aluminum (Al), copper (Cu), zinc (Zn), nickel (Ni), cobalt (Co), lead (Pb), platinum (Pt), molybdenum (Mo), ruthenium (Ru), or the like.

The first material layer 21 and the second material layer 22 may have different work functions, and the second material layer 22 may have a lower work function than the first material layer 21. The third material layer 23 and the fourth material layer 24 may have different work functions, and the fourth material layer 24 may have a lower work function than the third material layer 23. The fifth material layer 25 and the sixth material layer 26 may have different work functions, and the sixth material layer 26 may have a lower work function than the fifth material layer 25.

As an example, the first material layer 21, the third material layer 23, and the fifth material layer 25 may each include carbon, and the second material layer 22, the fourth material layer 24, and the sixth material layer 26 may each include at least one of tantalum (Ta), aluminum (Al), or titanium (Ti).

According to the structure described above, at least one of the first electrode E1, the second electrode E2, or the third electrode E3 may include the at least one adhesive layer. By including the adhesive layer in the electrodes E1, E2, and E3, it is possible to improve the adhesive force between the layers.

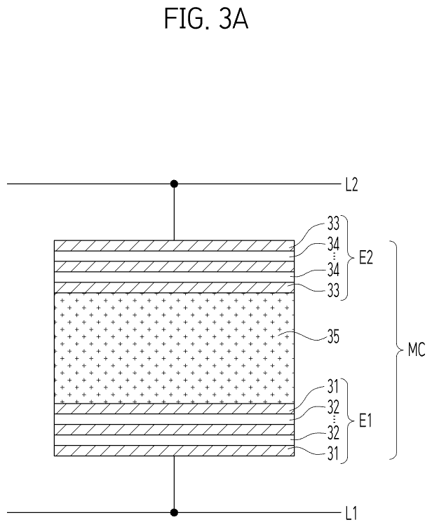

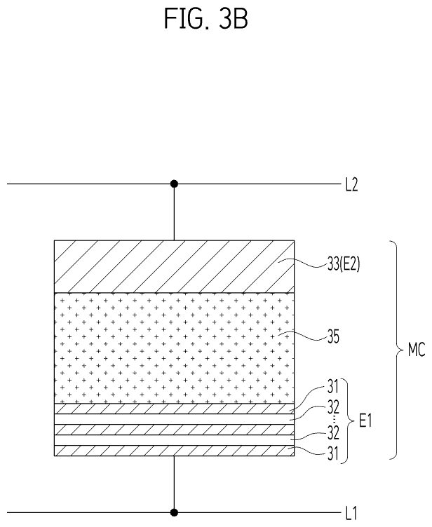

FIGS. 3A and 3B are diagrams for describing the structure of a semiconductor device in accordance with an embodiment. Hereinafter, the content overlapping with the previously described content may be omitted for the interest of brevity.

Referring to FIG. 3A, the semiconductor device may include a first access line L1, a second access line L2, and a memory cell MC. The memory cell MC may be connected between the first access line L1 and the second access line L2.

The memory cell MC may include a first electrode E1, a second electrode E2, and a variable resistance layer 35 located between the first electrode E1 and the second electrode E2. The variable resistance layer 35 may have an amorphous state, and may maintain the amorphous state without changing to a crystalline state after a program operation. Accordingly, a threshold voltage of the memory cell may be changed depending on a program voltage applied to the memory cell, and the memory cell may be programmed to at least two states. Data may be stored in the memory cell using a difference in the threshold voltage of the memory cell. The variable resistance layer 35 may be both a memory layer of a memory element and a switching layer of a selection element.

At least one of the first electrode E1 or the second electrode E2 may include an adhesive layer. Referring to FIG. 3A, both the first electrode E1 and the second electrode E2 may each have a laminate structure. The first electrode E1 may include at least one first material layer 31 and at least one second material layer 32 that are alternately stacked, and the second electrode E2 may include at least one third material layer 33 and at least one fourth material layer 34 that are alternately stacked. Here, the first material layer 31 and the third material layer 33 may be conductive layers serving as electrodes. The second material layer 32 and the fourth material layer 34 may be adhesive layers for increasing adhesive force between layers.

The first material layer 31 and the second material layer 32 may have different work functions. As an example, the second material layer 32 may have a lower work function than the first material layer 31. The third material layer 33 and the fourth material layer 34 may have different work functions. As an example, the fourth material layer 34 may have a lower work function than the third material layer 33. The first material layer 31 and the third material layer 33 may each include carbon, and the second material layer 32 and the fourth material layer 34 may each include at least one of tantalum (Ta), aluminum (Al), or titanium (Ti).

Referring to FIG. 3B, one of the first electrode E1 and the second electrode E2 may include an adhesive layer. As an example, the first electrode E1 may include at least one first material layer 31 and at least one second material layer 32 that are alternately stacked, and the second electrode E2 may include a third material layer 33. The first electrode E1 may include an adhesive layer, and the second electrode E2 might not include an adhesive layer.

According to the structure described above, the variable resistance layer 35 of the memory cell MC may serve as both a memory element and a selection element. In addition, at least one of the first electrode E1 or the second electrode E2 may include the adhesive layer, and may improve adhesive force between layers.

FIGS. 4A and 4B are diagrams for describing the structure of a semiconductor device in accordance with an embodiment. Hereinafter, the content overlapping with the previously described content may be omitted for the interest of brevity.

Referring to FIG. 4A, a memory cell MC may include a first electrode E1, a second electrode E2, and a variable resistance layer 45 located between the first electrode E1 and the second electrode E2. It is also possible for the memory cell MC to replace the variable resistance layer 45 with a switching layer (not shown) or to include both a variable resistance layer (not shown) and a switching layer (not shown) instead of the variable resistance layer 45.

The memory cell MC may further include a liner layer 48. The liner layer 48 may extend along a sidewall of the first electrode E1, a sidewall of the variable resistance layer 45, and a sidewall of the second electrode E2. The liner layer 48 may include nitride. As an example, the liner layer 48 may include silicon nitride, silicon boron nitride (SiBN), silicon carbonitride (SiCN), or the like.

The first electrode E1 may include a first material layer 41 and a second material layer 42 that have different work functions. As the first material layer 41 and the second material layer 42 have the different work functions, a work function difference between the first material layer 41 and the liner layer 48 and a work function difference between the second material layer 42 and the liner layer 48 may be different from each other. As an example, the liner layer 48 may have a higher work function than the first material layer 41 and the second material layer 42, and the second material layer 42 may have a lower work function than the first material layer 41. The first material layer 41 and the liner layer 48 may have a first work function difference therebetween, and the second material layer 42 and the liner layer 48 may have a second work function difference, which is greater than the first work function difference, therebetween.

The second electrode E2 may include a third material layer 43 and a fourth material layer 44 that have different work functions. As the third material layer 43 and the fourth material layer 44 have the different work functions, a work function difference between the third material layer 43 and the liner layer 48 and a work function difference between the fourth material layer 44 and the liner layer 48 may be different from each other. As an example, the liner layer 48 may have a higher work function than the third material layer 43 and the fourth material layer 44, and the fourth material layer 44 may have a lower work function than the third material layer 43. The third material layer 43 and the liner layer 48 may have a third work function difference therebetween, and the fourth material layer 44 and the liner layer 48 may have a fourth work function difference, which is greater than the first work function difference, therebetween. For example, the third work function difference between the third material layer 43 and the liner layer 48 may be substantially equal to the first work function difference between the first material layer 41 and the liner layer 48, or the fourth work function difference between the fourth material layer 44 and the liner layer 48 may be substantially equal to the second work function difference between the second material layer 42 and the liner layer 48, or both.

A work function difference between layers in contact with each other may affect adhesive force between the layers. When materials having different work functions are adhered to each other, electrons may move from a material having a low work function to a material having a high work function, and a potential difference may occur at an interface between the layers. When the potential difference occurs, an opposite electric field for preventing the movement of charges may be generated, and a dipole layer may be formed at the interface. The dipole layer may serve to electrically increase interfacial adhesive force. Accordingly, as the work function difference between the layers in contact with each other becomes greater, the adhesive force between the layers may increase.

Referring to FIG. 4B, a first electrode E1′ may include the first material layer 41 and might not include the second material layer 42. A second electrode E2′ may include the third material layer 43 and might not include the fourth material layer 44. In such a case, work function differences between the electrodes E1′ and E2′ and a liner layer 48′ may be relatively small, and adhesive force between the electrodes E1′ and E2′ and the liner layer 48′ may be relatively small.

A difference in adhesive force may affect a thickness of the liner layer 48′. The liner layer 48′ may have a first thickness T1′ on a sidewall of the variable resistance layer 45, may have a second thickness T2′, which is smaller than the first thickness T1′, on a sidewall of the first electrode E1′, and may have a third thickness T3′, which is smaller than the first thickness T1′, on a sidewall of the second electrode E2′. When the liner layer 48′ has a non-uniform thickness as described above, a profile of the memory cell may deteriorate. In addition, a material of the variable resistance layer 45 may diffuse through a portion having a relatively small thickness in the liner layer 48′, and cell characteristics may change as operations are performed on the memory cell MC.

A method of performing plasma treatment on the sidewalls of the electrodes E1′ and E2′ in order to increase the adhesive force between the electrodes E1′ and E2′ and the liner layer 48′ may be considered, but the variable resistance layer 45 may be damaged in a plasma treatment process. In addition, a method of adding an adhesive layer between the electrodes E1′ and E2′ and the liner layer 48′ may be considered, but an interval between the memory cells MC may become narrow and gap fill characteristics may deteriorate.

Accordingly, by including at least one adhesive layer in the electrodes E1 and E2, it is possible to increase the adhesive force between the electrodes E1 and E2 and the liner layer 48 without changing the profile of the memory cell or damaging the variable resistance layer 45. Referring back to FIG. 4A, the first electrode E1 may include first material layers 41 and second material layers 42 that are alternately stacked. A work function difference between the second material layers 42 and the liner layer 48 may be relatively great, and dipole layers may be formed at interfaces between the second material layers 42 and the liner layer 48. Accordingly, the adhesive force between the first electrode E1 and the liner layer 48 may be increased by the second material layers 42. In other words, since the work function difference between the second material layer 42 and the liner layer 48 is greater than that between the first material layer 41 and the liner layer 48, the adhesive force between the liner layer 48 and the first electrode E1 including the second material layers 42 in the embodiment of FIG. 4A may be increased compared to that when the first electrode E1′ includes only the first material layer 41 as shown in FIG. 4B.

A structure in which the first material layer 41 and the second material layer 42 are combined with each other may vary according to embodiments. A ratio, a thickness, and the like, of the second material layer 42 included in the first electrode E1 may be determined in consideration of the adhesive force between the first electrode E1 and the liner layer 48. When the ratio of the second material layer 42 is great, the adhesive force between the first electrode E1 and the liner layer 48 may be great, and when the thickness of the second material layer 42 is great, the adhesive force between the first electrode E1 and the liner layer 48 may be great.

Likewise, the second electrode E2 may include at least one third material layer 43 and at least one fourth material layer 44 that are alternately stacked. A work function difference between the fourth material layer 44 and the liner layer 48 may be relatively great, and a dipole layer may be formed at an interface between the fourth material layer 44 and the liner layer 48. Accordingly, the adhesive force between the second electrode E2 and the liner layer 48 may be increased by the fourth material layers 44.

A structure in which the third material layer 43 and the fourth material layer 44 are combined with each other may be variously changed. A ratio, a thickness, and the like, of the fourth material layer 44 included in the second electrode E2 may be determined in consideration of the adhesive force between the second electrode E2 and the liner layer 48. When the ratio of the fourth material layer 44 is great, the adhesive force between the second electrode E2 and the liner layer 48 may be great, and when the thickness of the fourth material layer 44 is great, the adhesive force between the second electrode E2 and the liner layer 48 may be great.

As the adhesive force between the electrodes E1 and E2 and the liner layer 48 increases, a thickness of the liner layer 48 on the sidewalls of the electrodes E1 and E2 may be increased. The liner layer 48 may have a first thickness T1 on the sidewall of the variable resistance layer 45, may have a second thickness T2, which is substantially the same as the first thickness T1, on the sidewall of the first electrode E1, and may have a third thickness T3, which is substantially the same as the first thickness T1, on the sidewall of the second electrode E2. For example, the increased work function difference between the second material layer 42 and the liner layer 48 may facilitate deposition of the liner layer 48 on a sidewall of the first electrode E1, significantly reducing a difference between the first thickness T1 of the liner layer 48 on the variable resistance layer 45 and the second thickness T2 of the liner layer 48 on the first electrode E1. Similarly, the increased work function difference between the fourth material layer 44 and the liner layer 48 may facilitate deposition of the liner layer 48 on a sidewall of the second electrode E2, significantly reducing a difference between the first thickness T1 of the liner layer 48 on the variable resistance layer 45 and the third thickness T3 of the liner layer 48 on the second electrode E2.

According to the structure described above, the first electrode E1 may include the second material layer 42, and the adhesive force between the first electrode E1 and the liner layer 48 may be increased by the second material layer 42. The second electrode E2 may include the fourth material layer 44, and the adhesive force between the second electrode E2 and the liner layer 48 may be increased by the fourth material layer 44.

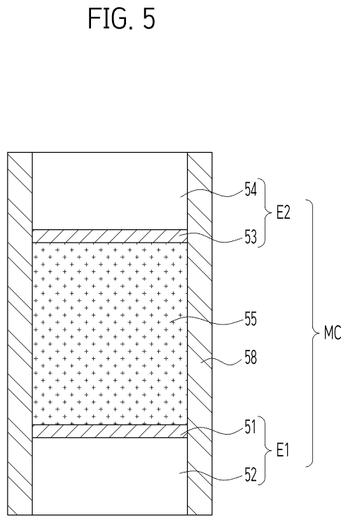

FIG. 5 is a diagram illustrating the structure of a semiconductor device in accordance with an embodiment. Hereinafter, the content overlapping with the previously described content may be omitted for the interest of brevity.

Referring to FIG. 5, a memory cell MC may include a first electrode E1, a second electrode E2, and a variable resistance layer 55 located between the first electrode E1 and the second electrode E2. It is also possible for the memory cell MC to replace the variable resistance layer 55 with a switching layer (not shown), or to include both a variable resistance layer (not shown) and a switching layer (not shown) instead of the variable resistance layer 55. The memory cell MC may further include a liner layer 58. The liner layer 58 may extend along a sidewall of the first electrode E1, a sidewall of the variable resistance layer 55, and a sidewall of the second electrode E2.

The first electrode E1 may include a first material layer 51 and a second material layer 52. Here, the first material layer 51 may have a smaller atomic size than the second material layer 52 and have denser physical properties than the second material layer 52. Accordingly, the first material layer 51 may function as a diffusion barrier and reduce diffusion of a material of the variable resistance layer 55. As an example, the first material layer 51 may include carbon, and the second material layer 52 may include at least one of tantalum (Ta), aluminum (Al), or titanium (Ti).

The first material layer 51 may be located at an interface between the variable resistance layer 55 and the first electrode E1 so as to effectively reduce the diffusion of the material of the variable resistance layer 55. That is, the variable resistance layer 55 and the first material layer 51 may be in contact with each other. In addition, the second material layer 52 may have a greater thickness than the first material layer 51 so as to increase adhesive force between the first electrode E1 and the liner layer 58. Specifically, the second material layer 52 has a work function lower than that of the first material layer 51 to make a second work function difference between the second material layer 52 and the liner layer 58 greater than a first work function difference between the first material layer 51 and the liner layer 58. As a result, adhesive force between the liner layer 58 and the first electrode E1 including both the first material layer 51 and the second material layer 52 increases compared to when the first electrode E1 includes only a single first material layer.

Likewise, the second electrode E2 may include a third material layer 53 and a fourth material layer 54. Here, the third material layer 53 may have a smaller atomic size than the fourth material layer 54 and have denser physical properties than the fourth material layer 54. Accordingly, the third material layer 53 may function as a diffusion barrier and reduce diffusion of the material of the variable resistance layer 55. As an example, the third material layer 53 may include carbon, and the fourth material layer 54 may include tantalum (Ta), aluminum (Al), or titanium (Ti).

The third material layer 53 may be located at an interface between the variable resistance layer 55 and the second electrode E2 so as to effectively reduce the diffusion of the material of the variable resistance layer 55. That is, the variable resistance layer 55 and the third material layer 53 may be in contact with each other. In addition, the fourth material layer 54 may have a greater thickness than the third material layer 53 so as to increase adhesive force between the second electrode E2 and the liner layer 58.

According to the structure described above, the first electrode E1 may include the first material layer 51 functioning as the diffusion barrier, and the second electrode E2 may include the third material layer 53 functioning as the diffusion barrier. In addition, the first and third material layers 51 and 53 may be located to be in contact with the variable resistance layer 55 to reduce the diffusion of the material of the variable resistance layer 55.

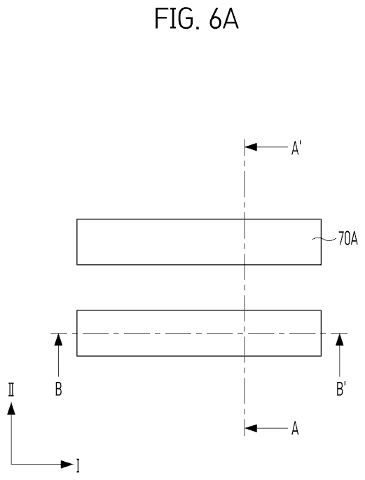

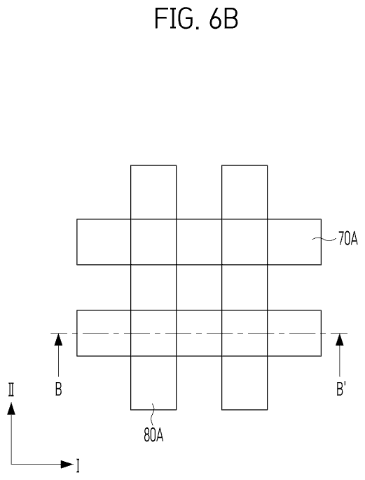

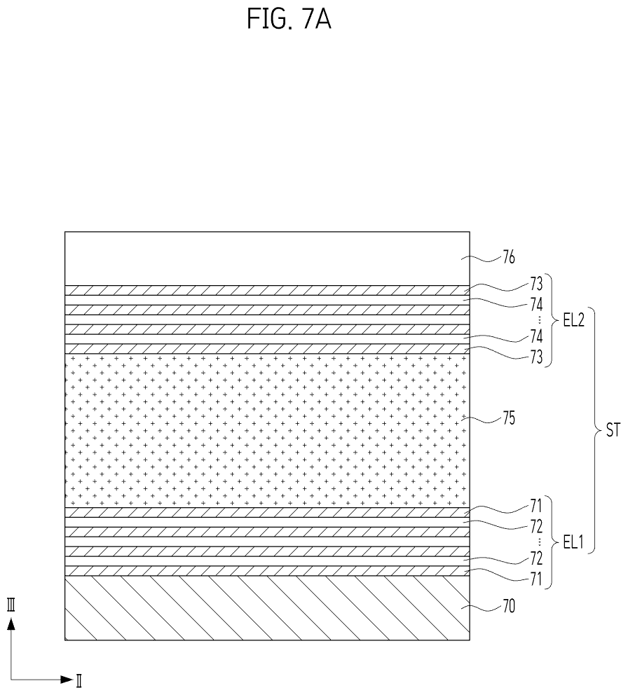

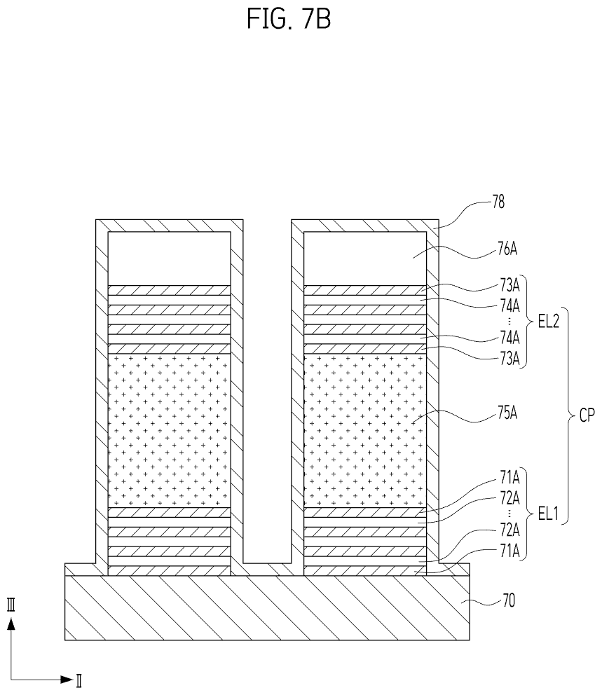

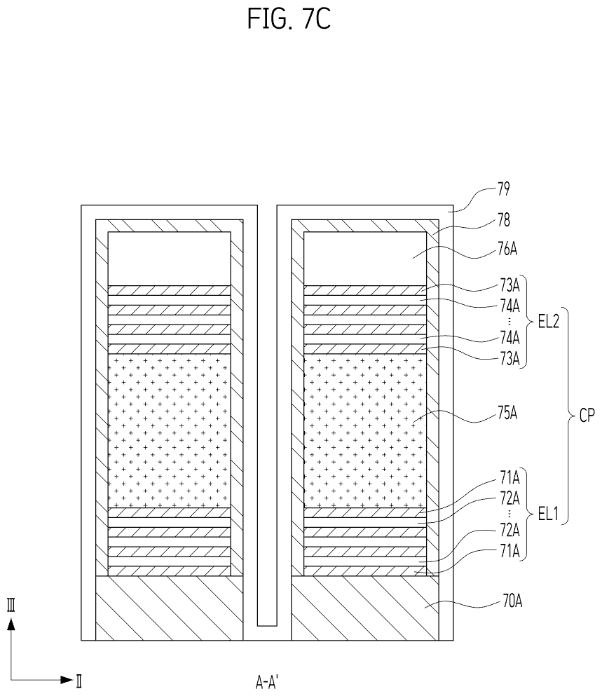

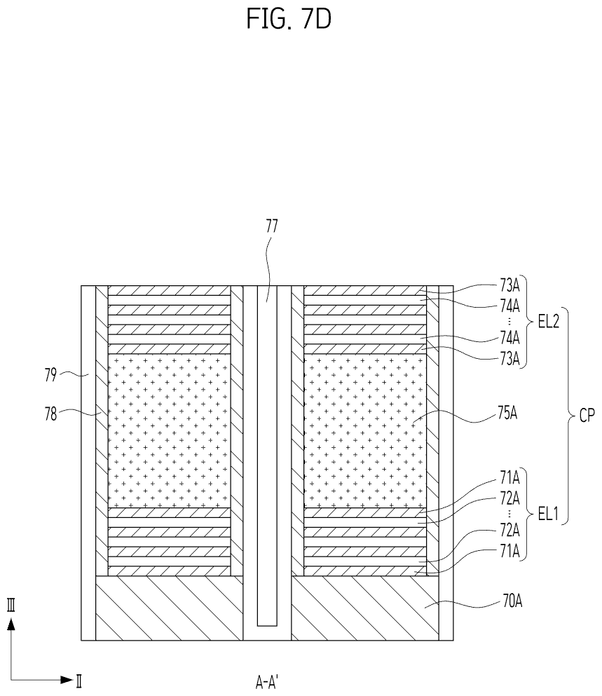

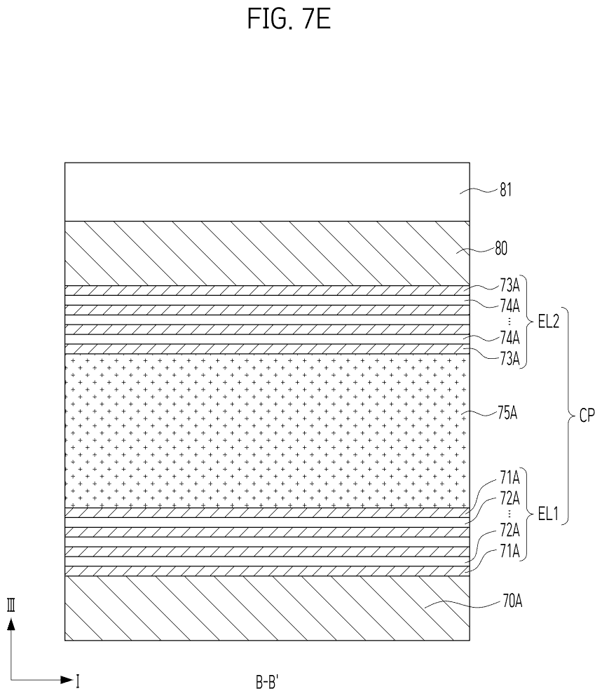

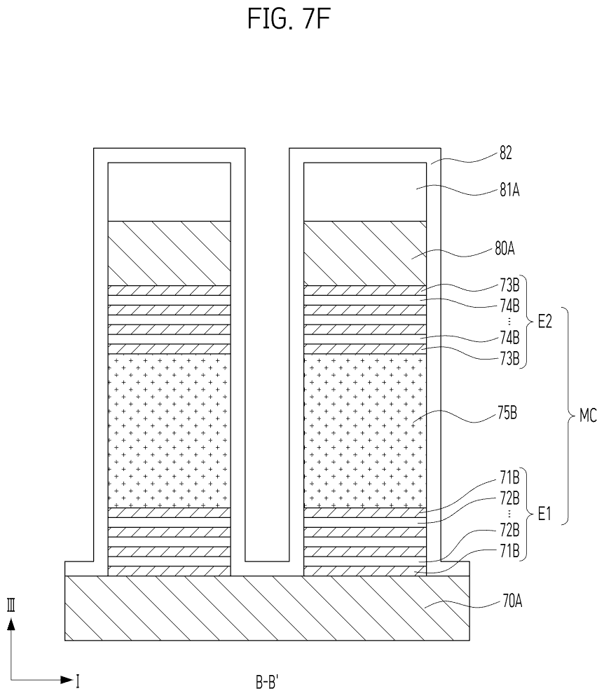

FIGS. 6A, 6B, and 7A to 7F are diagrams for describing a manufacturing method of a semiconductor device in accordance with an embodiment. FIGS. 7A to 7D are cross-sectional views in the second direction II, and FIGS. 7E and 7F are cross-sectional views in the first direction I. FIG. 6A is a plan view of FIGS. 7C to 7E, and FIG. 6B is a plan view of FIG. 7F. Hereinafter, the content overlapping with the previously described content may be omitted for the interest of brevity.

Referring to FIG. 7A, a first conductive layer 70 may be formed. The first conductive layer 70 may be used to form a first access line, and may include metal such as tungsten.

Subsequently, a stack ST may be formed on the first conductive layer 70. The stack ST may include a first electrode layer EL1, a variable resistance layer 75, and a second electrode layer EL2. For reference, it is also possible for the stack ST to include a switching layer (not shown) instead of the variable resistance layer 75 or include both the variable resistance layer 75 and the switching layer (not shown).

At least one of the first electrode layer (or first initial electrode layer) EL1 or the second electrode layer (or second initial electrode layer) EL2 may have a laminate structure. The first electrode layer EL1 may include at least one first material layer (or first initial material layer) 71 and at least one second material layer (or second initial material layer) 72 that are alternately stacked, and the first material layer 71 and the second material layer 72 may have different work functions. Here, the second material layer 72 may be an adhesive layer. For example, the first material layer 71 and the second material layer 72 may be formed in-situ. The second electrode layer EL2 may include at least one third material layer (or third initial material layer) 73 and at least one fourth material layer (or fourth initial material layer) 74 that are alternately stacked, and the third material layer 73 and the fourth material layer 74 may have different work functions. Here, the fourth material layer 74 may be an adhesive layer.

Subsequently, a hard mask 76 may be formed on the stack ST.

Referring to FIG. 7B, a hard mask pattern 76A extending in the first direction I may be formed by etching the hard mask 76. Subsequently, cell patterns CP may be formed by etching the stack ST using the hard mask pattern 76A as an etching barrier. The cell patterns CP may extend in the first direction I. Each of the cell patterns CP may include a first electrode layer EL1, a variable resistance layer 75A, and a second electrode layer EL2. The first electrode layer EL1 may include at least one first material layer (or first intermediate material layer) 71A and at least one second material layer (or second intermediate material layer) 72A that are alternately stacked, and the second electrode layer EL2 may include at least one third material layer (or third intermediate material layer) 73A and at least one fourth material layer (or fourth intermediate material layer) 74A that are alternately stacked.

Subsequently, a liner layer 78 may be formed. The liner layer 78 may be formed along profiles of the cell patterns CP. The liner layer 78 is used to protect the variable resistance layer 75A in a subsequent process, and may include nitride. As an example, the liner layer 78 may include silicon nitride, silicon boron nitride, silicon carbonitride, or the like.

The liner layer 78 may have a higher work function than the first material layer 71A and the second material layer 72A. The second material layer 72A may have a lower work function than the first material layer 71A. The first material layer 71A and the liner layer 78 may have a first work function difference therebetween and the second material layer 72A and the liner layer 78 may have a second work function difference therebetween, such that the second work function difference is greater than the first work function difference. Accordingly, adhesive force between the second material layer 72A and the liner layer 78 may be greater than adhesive force between the first material layer 71A and the liner layer 78, and the second material layer 72A may function as an adhesive layer.

The liner layer 78 may have a higher work function than the third material layer 73A and the fourth material layer 74A. The fourth material layer 74A may have a lower work function than the third material layer 73A. The third material layer 73A and the liner layer 78 may have a first work function difference therebetween and the fourth material layer 74A and the liner layer 78 may have a second work function difference therebetween, such that the second work function is greater than the first work function difference. Accordingly, adhesive force between the fourth material layer 74A and the liner layer 78 may be greater than adhesive force between the third material layer 73A and the liner layer 78, and the fourth material layer 74A may function as an adhesive layer.

The liner layer 78 may be formed by depositing a liner material along a sidewall of the variable resistance layer 75A, a sidewall of the first electrode layer EL1, and a sidewall of the second electrode layer EL2. In this case, as a work function difference between the sidewall and the liner material becomes greater, adhesive force may increase and a deposition thickness of the liner material may increase. When the first electrode layer EL1 includes only a single first material layer 71A, the adhesive force is relatively small, and thus, the liner material may be deposited at a smaller thickness on the sidewall of the first electrode layer EL1 than on the sidewall of the variable resistance layer 75A. When the first electrode layer EL1 includes the second material layers 72A, the adhesive force may be increased and a thickness of the liner material deposited on the sidewall of the first electrode layer EL1 may be increased. Similarly, when the second electrode layer EL2 includes the fourth material layers 74A, the adhesive force may be increased and a thickness of the liner material deposited on the sidewall of the second electrode layer EL2 may be increased compared to when the second electrode layer EL2 includes only a single third material layer 73A. Through this, the liner material may be deposited at a substantially uniform thickness along the sidewall of the variable resistance layer 75A, the sidewall of the first electrode layer EL1, and the sidewall of the second electrode layer EL2.

Referring to FIGS. 6A and 7C, first access lines 70A may be formed by etching the first conductive layer 70. When the first conductive layer 70 is etched, the variable resistance layer 75A may be protected with the liner layer 78. The first access line 70A may extend in the first direction I.

Subsequently, a protective layer 79 may be formed. The protective layer 79 may be formed along a profile of the liner layer 78, and may extend to sidewalls of the first access lines 70A. The protective layer 79 may include nitride.

Referring to FIGS. 6A and 7D, an insulating layer 77 may be formed between the cell patterns CP and between the first access lines 70A. The hard mask pattern 76A may be removed in a process of forming the insulating layer 77 by depositing and planarizing an insulating material. For example, after an insulating material is deposited on the protective layer 79 in FIG. 7C, upper portions of the insulating material and upper portions of the liner layer 78 as well as the hard mask pattern 76A may be removed by planarizing until an uppermost third material layer 73A of the second electrode layer EL2 is exposed.

Referring to FIGS. 6A and 7E, a second conductive layer 80 may be formed on the cell patterns CP and the insulating layer 77. The second conductive layer 80 may be used to form a second access line, and may include metal such as tungsten. Subsequently, a hard mask 81 may be formed on the second conductive layer 80.

Referring to FIGS. 6B and 7F, a hard mask pattern 81A extending in the second direction II intersecting the first direction I may be formed by etching the hard mask 81. Subsequently, second access lines 80A extending in the second direction II may be formed by etching the second conductive layer 80 using the hard mask pattern 81A as an etching barrier. Subsequently, memory cells MC may be formed by etching the cell patterns CP and the insulating layer 77. The memory cells MC may be respectively located in intersection regions between the first access lines 70A and the second access lines 80A. Subsequently, a protective layer 82 may be formed on sidewalls of the memory cells MC.

Each of the memory cells MC may include a first electrode E1, a variable resistance layer 75B, and a second electrode E2. The first electrode E1 may include at least one first material layer 71B and at least one second material layer 72B that are alternately stacked, and the second electrode E2 may include at least one third material layer 73B and at least one fourth material layer 74B that are alternately stacked.

According to the manufacturing method described above, it is possible to increase the adhesive force of the liner layer 78 by including the adhesive layers in the electrode layers EL1 and EL2. Accordingly, the liner layer 78 having a substantially uniform thickness may be formed on a sidewall of the memory cell MC.

Although embodiments according to the technical idea of the present disclosure have been described above with reference to the accompanying drawings, this is only for explaining the embodiments according to the concept of the present disclosure, and various embodiments of the present disclosure are not limited to the above embodiments. Various types of substitutions, modifications, changes, and combinations for the embodiments may be made by those skilled in the art, to which the present disclosure pertains, without departing from the technical idea of the present disclosure defined in the following claims, and it should be construed that these substitutions, modifications, changes, and combinations belong to the scope of the present disclosure.

What is claimed is:

1. A semiconductor device comprising:
a first electrode including at least one first material layer and at least one second material layer that are alternately stacked, the first material layer and the second material layer having different work functions;
a second electrode; and
a variable resistance layer located between the first electrode and the second electrode.

2. The semiconductor device of claim 1, further comprising a liner layer extending along a sidewall of the first electrode, a sidewall of the variable resistance layer, and a sidewall of the second electrode.

3. The semiconductor device of claim 2, wherein the first material layer and the liner layer have a first work function difference therebetween, and the second material layer and the liner layer have a second work function difference therebetween, the second work function difference being greater than the first work function difference.

4. The semiconductor device of claim 2, wherein the liner layer has a work function higher than that of the first material layer, and the second material layer has a work function lower than that of the first material layer.

5. The semiconductor device of claim 4, wherein adhesive force between the second material layer and the liner layer is greater than adhesive force between the first material layer and the liner layer.

6. The semiconductor device of claim 2, wherein the first material layer includes carbon, the second material layer includes at least one of tantalum (Ta), aluminum (Al), or titanium (Ti), and the liner layer includes nitride.

7. The semiconductor device of claim 1, wherein the first material layer has an atomic size smaller than that of the second material layer, and
wherein the variable resistance layer and the first material layer are in contact with each other.

8. The semiconductor device of claim 1, wherein the second electrode includes at least one third material layer and at least one fourth material layer that are alternately stacked, and the third material layer and the fourth material layer have different work functions.

9. A semiconductor device comprising:
a first electrode including first conductive layers and first adhesive layers that are alternately stacked;
a second electrode;
a variable resistance layer located between the first electrode and the second electrode; and
a liner layer extending along a sidewall of the first electrode and in contact with the first adhesive layers.

10. The semiconductor device of claim 9, wherein the liner layer and each of the first conductive layers have a first work function difference therebetween, and the liner layer and each of the first adhesive layers have a second work function difference therebetween, the second work function difference being greater than the first work function difference.

11. The semiconductor device of claim 9, wherein the second electrode includes second conductive layers and second adhesive layers that are alternately stacked.

12. A manufacturing method of a semiconductor device, the manufacturing method comprising:
forming a first electrode layer including at least one first material layer and at least one second material layer that are alternately stacked, the first material layer and the second material layer having different work functions;
forming a variable resistance layer on the first electrode layer; and
forming a second electrode layer on the variable resistance layer.

13. The manufacturing method of claim 12, further comprising forming a liner layer along a sidewall of the first electrode layer, a sidewall of the variable resistance layer, and a sidewall of the second electrode layer.

14. The manufacturing method of claim 13, wherein the first material layer and the liner layer have a first work function difference therebetween, and the second material layer and the liner layer have a second work function difference therebetween, the second work function difference being greater than the first work function difference.

15. The manufacturing method of claim 13, wherein adhesive force between the second material layer and the liner layer is greater than adhesive force between the first material layer and the liner layer.

16. The manufacturing method of claim 13, wherein the first material layer includes carbon, the second material layer includes at least one of tantalum (Ta), aluminum (Al), or titanium (Ti), and the liner layer includes nitride.

17. The manufacturing method of claim 12, wherein the first material layer has an atomic size smaller than that of the second material layer, and
wherein the variable resistance layer and the first material layer are in contact with each other.

18. The manufacturing method of claim 12, wherein in the forming of the first electrode layer, the first material layer and the second material layer are formed in-situ.

19. The manufacturing method of claim 12, wherein in the forming of the second electrode layer, at least one third material layer and at least one fourth material layer are alternately stacked on the variable resistance layer, and the third material layer and the fourth material layer have different work functions.

20. The manufacturing method of claim 19, further comprising forming a liner layer along a sidewall of the first electrode layer, a sidewall of the variable resistance layer, and a sidewall of the second electrode layer,
wherein adhesive force between the fourth material layer and the liner layer is greater than adhesive force between the third material layer and the liner layer.
